(19) United States
(12) Patent Application Publication
(10) Pub. No.: US 2026/0271676 A1
(43) Pub. Date: Sep. 10, 2026

(54) WAFER PROCESSING METHOD

(71) Applicant: ProAsia Semiconductor Corporation, Hsinchu (TW)

(72) Inventor: Hsi-Chih Chen, Hsinchu (TW)

(21) Appl. No.: 19/556,196

(22) Filed: Mar. 4, 2026

(30) Foreign Application Priority Data
Mar. 6, 2025 (TW) 114108334

(51) Int. Cl. H10P 74/20; H10W 46/00

(52) U.S. Cl. CPC H10P 74/203; H10W 46/503

(57) ABSTRACT

This invention provides a wafer processing method, including following steps: providing a wafer including a plurality of dies and a plurality of blank areas defined near edges of each die; and performing photolithography processes N times to form N-layer pattern contours on a surface of each die, wherein, except the last photolithography process, each of the remaining N photolithography processes forms a ruler pattern group correspondingly on one of the plurality of blank areas, wherein, except the first photolithography process, each of the remaining N photolithography processes forms a mark pattern correspondingly on each ruler pattern group, already formed, and wherein N is an integer not less than 2. By inspecting a relative position of any mark pattern formed on any ruler pattern group, whether the pattern contour of the corresponding layer exhibits abnormalities can be determined.

### CROSS REFERENCE TO RELATED APPLICATION

This application claims the benefit of Taiwan Patent Application Serial No. 114108334 filed on March 6, 2025. The entirety of each Application is incorporated herein by reference.

### BACKGROUND OF THE INVENTION

### Field of the Invention

The present invention relates to a wafer processing method, especially a wafer processing method for easily inspecting abnormalities in pattern contours of dies.

### Description of Related Art

Generally, semiconductor wafers, after a series of manufacturing processes have performed thereon, should undergo wafer acceptance tests (WAT) and yield tests (YIELD) to ensure that the wafers have a certain level of quality and stability before leaving the factory. When an abnormality is detected after WAT or YIELD, cross-sectional slice analyzing on the wafer is necessary for conventional ways, so as to speculate which process has problems. It is both time-consuming and laborious. Furthermore, whether abnormal or offset situations occur for a pattern contour on a surface of a wafer cannot be immediately determined simply by inspecting an appearance of the wafer alone. Consequently, when an abnormality is detected after a chip is subsequently packaged, it is impossible to trace back for determining whether the corresponding chips of the same batch have the same problem.

In light of this, it is really worthy of research and development to design a wafer processing method for solving those above-mentioned problems.

### SUMMARY OF THE INVENTION

An objective of the present invention is to provide a wafer processing method which is able to instantly inspect abnormalities in the pattern contours without cross-sectional slice analyzing.

To achieve the above mentioned objective, the wafer processing method comprises following steps: providing a wafer, wherein the wafer includes a plurality of dies and a plurality of blank areas defined near edges of each die; and performing photolithography processes N times to form N-layer pattern contours on a surface of each die, wherein, except the last photolithography process, each of the remaining N photolithography processes forms a ruler pattern group correspondingly on one of the plurality of blank areas, wherein, except the first photolithography process, each of the remaining N photolithography processes forms a mark pattern correspondingly on each ruler pattern group, already formed , and wherein N is an integer not less than 2. By inspecting a relative position of any mark pattern on any ruler pattern group, whether the pattern contour of the corresponding layer exhibits abnormalities can be determined.

In one embodiment of the present invention, in each photolithography process, a linewidth of the pattern contour of one layer is equal to a linewidth of the mark pattern formed on each ruler pattern group in the same photolithography process.

In one embodiment of the present invention, a M^{th} photolithography process is correspondingly performed through a M^{th} photomask for each die, M is an integer, and M = 1 to (N-1). When M = 1, the M^{th} photomask includes a M^{th} pattern contour area and a M^{th} ruler pattern area. When M > 1, the M^{th} photomask includes the M^{th} pattern contour area, the M^{th} ruler pattern area, and a (M-1)^{th} mark pattern area.

In one embodiment of the present invention, a N^{th} photolithography process is correspondingly performed through a N^{th} photomask for each die, and the N^{th} photomask includes a N^{th} pattern contour area and a (N-1)^{th} mark pattern area.

In one embodiment of the present invention, the N^{th} photomask further includes a number pattern area.

In one embodiment of the present invention, through performing the M^{th} photolithography process, the M^{th} ruler pattern group is formed. The M^{th} ruler pattern group includes a first ruler pattern extending along a first direction, and the first ruler pattern has (N-M) first scale sections.

In one embodiment of the present invention, each first scale section has two first measuring segments, arranged along the first direction on opposite sides of the first scale section respectively, and at least one first scale gradation is provided along the first direction on each first measuring section.

In one embodiment of the present invention, the M^{th} ruler pattern group further includes a second ruler pattern extending along a second direction, the second ruler pattern has (N-M) second scale sections, and the second direction is perpendicular to the first direction.

In one embodiment of the present invention, each second scale section has two second measuring segments, arranged along the second direction on opposite sides of the second scale section respectively, and at least one second scale gradation is provided along the second direction on each second measuring section.

In one embodiment of the present invention, the wafer processing method further comprises a following step: forming a number pattern on the surface of another one of the plurality of blank areas on each die in the N^{th} photolithography process.

### BRIEF DESCRIPTION OF THE DRAWINGS

FIG. 1 is a flowchart of a wafer processing method according to the present invention;

FIG. 2 is a schematic diagram of a wafer provided in the wafer processing method according to the present invention;

FIG. 3 is a schematic diagram of a single ruler pattern group and a mark pattern formed by the wafer processing method according to the present invention;

FIG. 4 is a schematic view of a photomask applied in the wafer processing method according to the present invention;

FIG. 5 is a schematic diagram of a specific blank area after performing the first photolithography process on one single die of the wafer processing method according to the present invention;

FIG. 6 is a schematic diagram of the specific blank area after performing the second photolithography process on the single die of the wafer processing method according to the present invention;

FIG. 7 is a schematic diagram of the specific blank area after performing the third photolithography process on the single die of the wafer processing method according to the present invention;

FIG. 8 is a schematic diagram of the specific blank area after performing the final photolithography process on the single die of the wafer processing method according to the present invention;

FIG. 9 is a schematic diagram showing another embodiment with one single ruler pattern group and one mark pattern formed by the wafer processing method according to the present invention; and

FIG. 10 is a schematic diagram showing one number pattern of the wafer processing method according to the present invention.

### DETAILED DESCRIPTION OF THE PREFERRED EMBODIMENT

Since various examples and embodiments in the present invention are only illustrative and non-restrictive, a person skilled in the art can easily conceive other examples and embodiments without contravening the scope of the present invention, after reading this specification, and can make the features and advantages of these embodiments more evident based on the following detailed description and claims.

Herein, the description of unit, element and component in the present invention uses “one”, “a”, or “an”. This is for convenience and for offering general meaning of the category of the present invention. Therefore, the description should be understood as including “one”, “at least one”, and singular and plural forms at the same time unless the context clearly indicates otherwise.

Herein, the description of the terms "first" or "second" and similar ordinal numbers are mainly used to distinguish or refer to the same or similar elements or structures and do not necessarily imply that such components or structures are spatially or temporally distinct order. It should be understood that ordinal numbers, in certain situations or configurations, may be used interchangeably without affecting the implementation of the present invention.

Herein, the description of “comprise”, “have” or other similar semantics have the non-exclusive meaning. For example, components or structures with a plurality of elements are not only limited to those disclosed in this specification, but also include generally inherent elements, which are not explicitly listed here for the components or the structures.

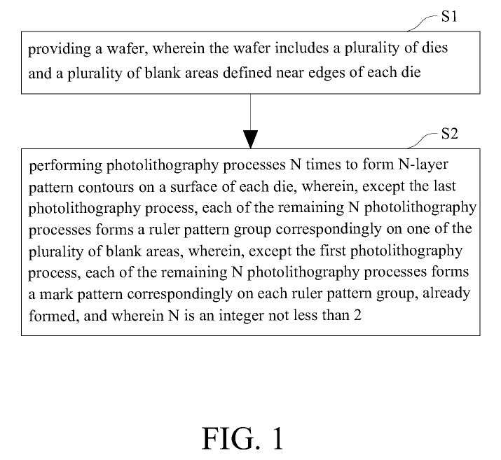

The present invention primarily relates to forming measurable scales and patterns to be inspected on the surface of the dies in the processing of semiconductor wafers (particularly in the photolithography process), so as to facilitate subsequent outgoing quality controls of chips. Please refer to FIG. 1, which is a flowchart of the wafer processing method according to the present invention. As shown in FIG. 1, the wafer processing method of the present invention comprises following steps.

Step S1: providing a wafer 1000, wherein the wafer 1000 including a plurality of dies 1 and a plurality of blank areas 12 defined near edges of each die 1.

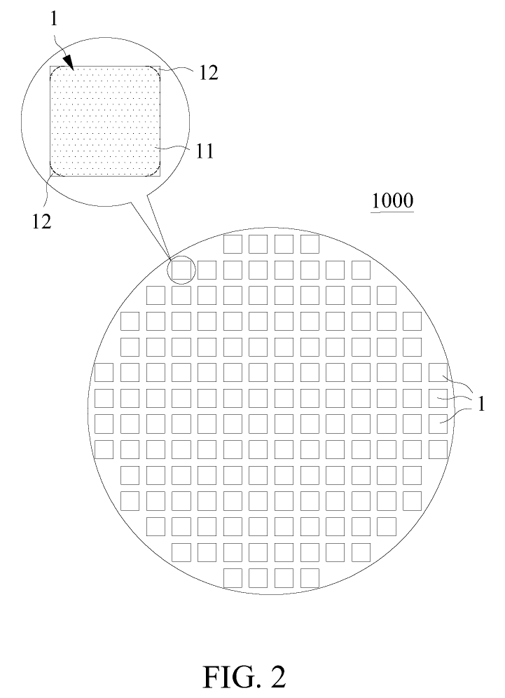

Please refer to FIGS. 1 and 2 together, wherein FIG. 2 is a schematic diagram of a wafer 1000 provided in the wafer processing method according to the present invention. As shown in FIGS. 1 and 2, the present invention provides a wafer 1000 at the beginning. Herein, wafer 1000 is illustrated by a circular silicon wafer as an example, but shapes and materials of the wafer 1000 are not limited thereto. A plurality of dies 1 are formed on a surface of the wafer 1000. Each die 1 is rectangular in shape, with a functional main portion 11 defined inwardly from edges of each die 1, and with a plurality of non-functional blank areas 12 located near the edges of the die 1 (that is, between the main portion 11 and the edges). For example, as shown in FIG. 2, each main portion 11 of each die 1 is generally a rounded rectangle, and the plurality of blank areas 12 are formed at four corners outside the main portion 11. However, the shapes and the positions of the plurality of blank areas 12 are not limited thereto.

Step S2: performing photolithography processes N times to form N-layer pattern contours on a surface of each die 1, wherein, except the last photolithography process, each of the remaining N photolithography processes forms a ruler pattern group 2 correspondingly on one of the plurality of blank areas 12, wherein, except the first photolithography process, each of the remaining N photolithography processes forms a mark pattern 3 correspondingly on each of the ruler pattern groups 2,which are already formed, and wherein N is an integer not less than 2.

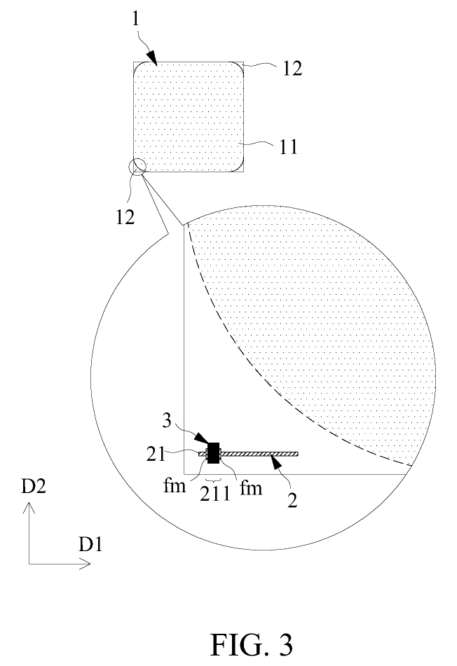

Refer also to FIGS. 1 and 3, wherein FIG. 3 is a schematic diagram of a single ruler pattern group 2 and a mark pattern 3 formed by the wafer processing method according to the present invention. As shown in FIGS. 1 and 3, after the wafer 1000 is provided in the aforementioned Step S1, the photolithography processes are performed for N times on each die 1 of the wafer 1000, so that N-layer pattern contours form on the surface of each die 1. That is, after each photolithography process is performed, one pattern contour of one corresponding layer is formed on the surface of die 1. The N-layer pattern contours are stacked to serve as a circuit pattern required for the die 1. And after each photolithography process is performed, the corresponding ruler pattern group 2 and/or the mark pattern 3 are formed on one of the plurality of blank areas 12 on each die 1. Herein, N is an integer not less than 2.

In terms of design, during the N photolithography processes, except the final photolithography process (i.e., from the first photolithography process to the (N-1)^{th} photolithography process), each photolithography process forms one the ruler pattern group 2 on one of the plurality of blank areas 12. That is, through the N photolithography processes, only (N-1) ruler pattern groups 2 are formed, and the (N-1) ruler pattern groups 2 may be selectively formed on the same or different blank areas 12.

In terms of design, during the N photolithography processes, except the first photolithography process (i.e., from the second photolithography process to the N^{th} photolithography process), each photolithography process forms one mark pattern 3 on one corresponding position of each ruler pattern group 2 formed by those photolithography processes that are previously performed. That is to say, any ruler pattern group 2 must be previously formed on one of the plurality of blank areas 12, so that the mark pattern 3 can be subsequently formed on the corresponding position of the formed ruler pattern group 2. Therefore, the formation of the mark pattern 3 must be excluded from the first photolithography process.

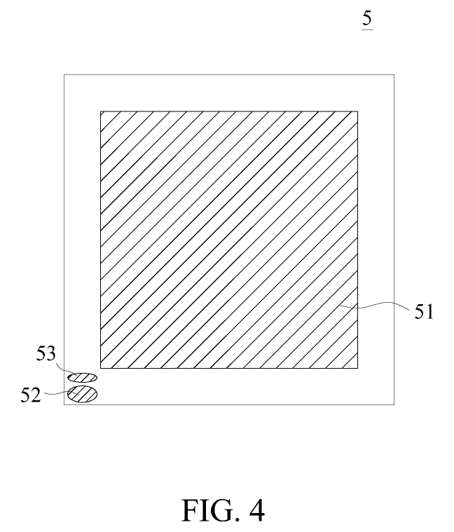

Please refer to FIGS. 3 and 4 together, wherein FIG. 4 is a schematic diagram of a photomask 5 applied in the wafer processing method according to the present invention. As shown in FIGS. 3 and 4, in the present invention, each photolithography process correspondingly utilizes one different photomask 5 to form one different pattern contour of one layer on the surface of the die 1, as well as one ruler pattern group 2 and/or one mark pattern 3. In one embodiment of the present invention, each photomask 5 applied therein must include a pattern contour area 51 and selectively includes a ruler pattern area 52 and/or a mark pattern area 53, depending on the different photolithography process to which the photomask 5 is applied. According to different designs or requirements, each photomask 5 may use to perform the corresponding photolithography process on only one single die 1, or each photomask 5 may simultaneously use to perform the corresponding photolithography process on a plurality of dies 1.

In one embodiment of the present invention, the M^{th} photolithography process is correspondingly performed through the M^{th} mask 5 for each die 1. Wherein M is an integer and M = 1 to (N-1). When M = 1, the M^{th} photomask includes the M^{th} pattern contour area and the M^{th} ruler pattern area, such that the mark pattern 3 is not formed in the M^{th} photolithography process (i.e., the first photolithography process). When M > 1, the M^{th} photomask includes the M^{th} pattern contour area, the M^{th} ruler pattern area, and the (M-1)^{th} mark pattern area, such that the pattern contour, the ruler pattern 2 and the mark pattern 3 are formed in the M^{th} photolithography process (i.e., any one of the 2nd to (N-1)^{th} photolithography processes).

In one embodiment of the present invention, for each die 1, the N^{th} photolithography process is correspondingly performed through the N^{th} photomask, and the N^{th} photomask includes the N^{th} pattern contour area and the (N-1) ^{th} mark pattern area, so that the ruler pattern group 2 does not form in the N^{th} photolithography process (i.e., the final photolithography process).

In one embodiment of the present invention, the M^{th} photolithography process is performed to form the M^{th} ruler pattern group 2. The M^{th} ruler pattern group 2 includes a first ruler pattern 21 extending along a first direction D1, wherein the first direction D1 is parallel to one side edge of the die 1. The first ruler pattern 21 has (N-M) first scale sections 211. That is, a number of first scale sections 211 contained in the first ruler pattern 21 of the M^{th} ruler pattern group 2 decreases as the corresponding M increases. Each first scale section 211 provides a relative inspecting function for the corresponding mark pattern 3 formed on that first scale section 211.

In one embodiment of the present invention, each first scale section 211 has two first measuring segments fm. The two first measuring segments fm are arranged along the first direction D1 on opposite sides of the first scale section 211 respectively, and at least one first scale gradation provided along the first direction D1 on each first measuring section fm. When the mark pattern 3, formed in each photolithography process, is formed on the corresponding first scale section 211, by determining a position of a linewidth of the mark pattern 3 on the first scale gradation of each first measuring segment fm of the corresponding first scale section 211, it is possible to detect whether the pattern contour of the corresponding layer of that photolithography process exhibits abnormalities (e.g., the linewidth of the pattern contour changes or the pattern contour offsets).

In one embodiment of the present invention, the linewidth of each first scale section 211 of the first ruler pattern 21 for inspecting the mark pattern 3 may be adjusted according to the linewidth of the pattern contour of the corresponding layer. This allows each first scale section 211 of the first ruler pattern 21 to potentially have the same or different dimensions. In one embodiment of the present invention, any two adjacent first first scale sections 211 of the first ruler pattern 21 maintain a spacing which is not less than 1 µm.

In one embodiment of the present invention, the linewidth of the pattern contour of one layer formed by each photolithography process is equal to the linewidth of the mark pattern 3 formed on each ruler pattern group 2 in the same photolithography process. Therefore, if any mark pattern 3 on the die 1 exhibits a line-offset or a linewidth variation relative to the corresponding ruler pattern group 2, it indicates that potential abnormalities occur in the pattern contour of that layer formed together with the mark pattern 3 in the same photolithography process. Thus, the affected die 1 can be rapidly sorted out for being instantly treated.

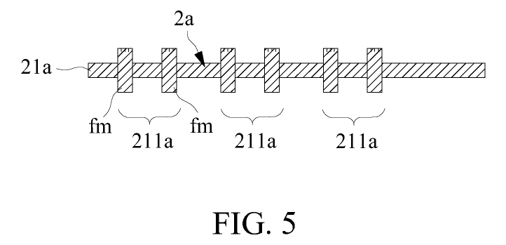

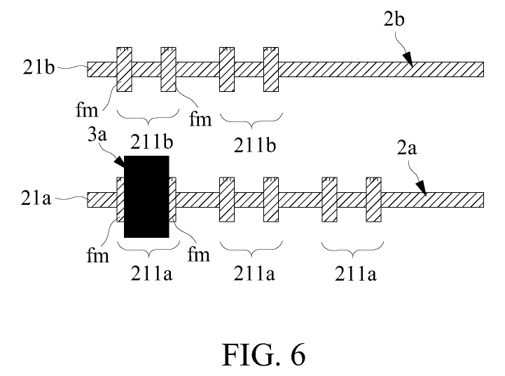

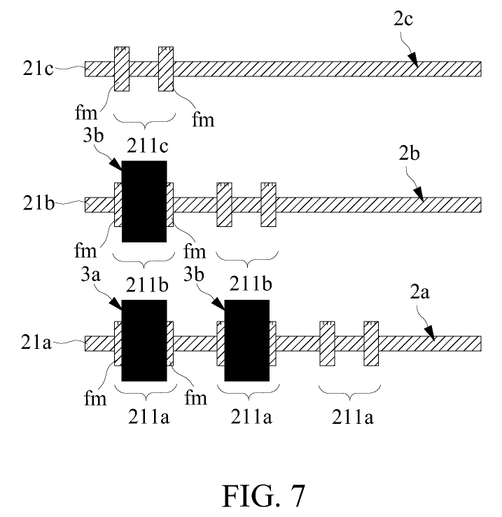

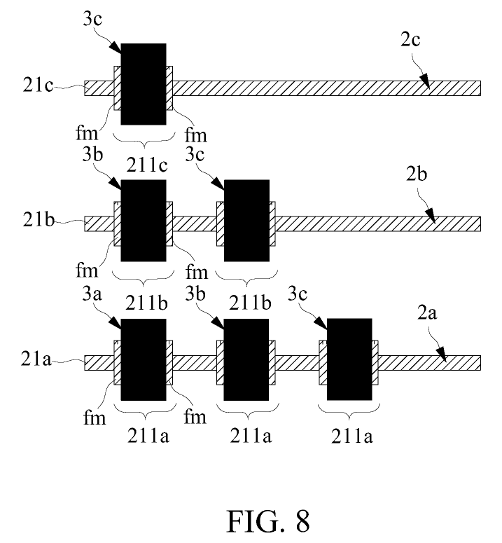

The following embodiments illustrate the wafer processing method of the present invention. Please refer to FIGS. 2 and 5 through 8. FIG. 5 is a schematic diagram of a specific blank area 12 after performing the first photolithography process on one single die 1 of the wafer processing method according to the present invention. FIG. 6 is a schematic diagram of the specific blank area 12 after performing the second photolithography process on the single die 1 of the wafer processing method according to the present invention. FIG. 7 is a schematic diagram of the specific blank area 12 after performing the third photolithography process on the single die 1 of the wafer processing method according to the present invention. FIG. 8 is a schematic diagram of the specific blank area 12 after performing the final photolithography process on the single die 1 of the wafer processing method according to the present invention. In one embodiment of the present invention, it is assumed that four photolithography processes are required for each die 1 totally, wherein N = 4 and M = 1 to 3.

As shown in FIGS. 2 and 5, after the first photolithography process is performed, one pattern contour of a first layer is formed on a surface of the main portion 11 of each die 1, and one first ruler pattern group 2a is formed on any blank area 12 of each die 1. The first ruler pattern group 2a may include a first ruler pattern 21a, and the first ruler pattern 21a of the first ruler pattern group 2a has three first scale sections 211a.

As shown in FIGS. 2 and 6, after the second photolithography process is performed, one pattern contour of a second layer is formed on the surface of the main portion 11 of each die 1, and one second ruler pattern group 2b is formed on the same (or different) blank area(s) 12 of each die 1. Also, one mark pattern 3a is formed on one of the corresponding first scale sections 211a of the formed first ruler pattern group 2a. The second ruler pattern group 2b may include one first ruler pattern 21b, and the first ruler pattern 21b of the second ruler pattern group 2b has two first scale sections 211b.

As shown in FIGS. 2 and 7, after the third photolithography process is performed, one pattern contour of a third layer is formed on the surface of the main portion 11 of each die 1, and one third ruler pattern group 2c is formed on the same (or different) blank area(s) 12 of each die 1. Also, mark patterns 3b are respectively formed on one of the corresponding first scale sections 211a of the formed first ruler pattern group 2a and on one of the corresponding first scale sections 211b of the formed second ruler pattern group 2b. The third ruler pattern group 2c may include one first ruler pattern 21c, and the first ruler pattern 21c of the third ruler pattern group 2c has one first scale section 211c.

As shown in FIGS. 2 and 8, after the fourth photolithography process is performed, one pattern contour of a fourth layer is formed on the surface of the main portion 11 of each die 1, and mark patterns 3c are respectively formed on one of the corresponding first scale section 211a of the formed first ruler pattern group 2a, on one of the corresponding first scale section 211b of the second ruler pattern group 2b, and on one of the corresponding first scale section 211c of the third ruler pattern group 2c.

Accordingly, by performing the photolithography processes four times, the pattern contours of four layers in total are stacked on the surface of the main portion 11 of each die 1, and three sets of ruler pattern groups 2a, 2b and 2c, along with their corresponding mark patterns 3a, 3b and 3c, are formed on the surface of one blank area 12 of each die 1. For the first ruler pattern group 2a, whether the pattern contour of the second layer exhibits abnormalities relative to the pattern contour of the first layer can be determined by checking a relative position of the mark pattern 3a on the first ruler pattern group 2a; whether the pattern contour of the third layer exhibits abnormalities relative to the pattern contour of the first layer can be determined by checking a relative position of the mark pattern 3b on the first ruler pattern group 2a; while whether the pattern contour of the fourth layer exhibits abnormalities relative to the pattern contour of the first layer can be determined by checking a relative position of the mark pattern 3c on the first ruler pattern group 2a. For the second ruler pattern group 2b, whether the pattern contour of the third layer exhibits abnormalities relative to the pattern contour of the second layer can be determined by checking a relative position of the mark pattern 3b on the second ruler pattern group 2b; while whether the pattern contour of the fourth layer exhibits abnormalities relative to the pattern contour of the second layer can be determined by checking a relative position of the mark pattern 3c on the second ruler pattern group 2b. For the third ruler pattern group 2c, whether the pattern contour of the fourth layer exhibits abnormalities relative to the pattern contour of the third layer can be determined by checking a relative position of the mark pattern 3c on the third ruler pattern group 2c.

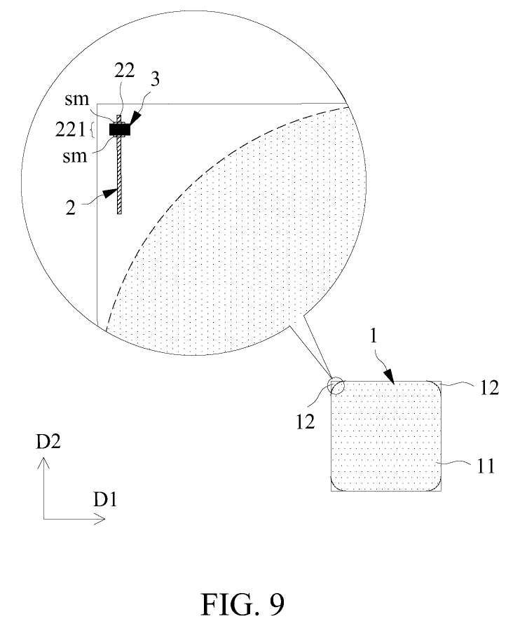

Refer also to FIGS. 3 and 9, wherein FIG. 9 is a schematic diagram showing another embodiment with one single ruler pattern group 2 and one mark pattern 3 formed by the wafer processing method according to the present invention. As shown in FIGS. 3 and 9, in one embodiment of the present invention, the M^{th} ruler pattern group 2 includes not only the aforementioned first ruler pattern 21 extending along the first direction D1, but also a second ruler pattern 22 extending along a second direction D2. The second direction D2 is perpendicular to the first direction D1 and parallel to another side edge of the die 1. In this embodiment, the first ruler pattern 21 and the second ruler pattern 22 of the M^{th} ruler pattern group 2 are respectively formed on the surfaces of different blank areas 12 of the die 1. However, depending on different designs or requirements, the first ruler pattern 21 and the second ruler pattern 22 may also both be formed on the surface of the same blank area 12 of the die 1.

As shown in FIG. 9, the second ruler pattern 22 has (N-M) second scale sections 221. That is, a number of second scale sections 221 contained in the second ruler pattern 22 of the M^{th} ruler pattern group 2 decreases as corresponding M increases. Each second scale section 221 provides a corresponding inspecting function for the mark pattern 3 formed on that second scale section 221.

In one embodiment of the present invention, each second scale section 221 has two second measuring segments sm. The two second measuring sections sm are arranged along the second direction D2 on opposite sides of the second scale section 221 respectively, and at least one second scale gradation is provided along the second direction D2 on each second measuring section sm. When the mark pattern 3, formed in each photolithography process, is formed on the corresponding second scale section 221, by determining a position of the linewidth of the mark pattern 3 on the second scale gradation of each second measuring segment sm of the corresponding second scale section 221, it is possible to detect whether the pattern contour of the corresponding layer of that photolithography process exhibits abnormalities (e.g., the linewidth of the pattern contour changes or the pattern contour offsets). In terms of design, the linewidth of the mark pattern 3 formed in each photolithography process falls between the shortest and the longest distances, along the second direction D2, between the two second measurement sections sm of the corresponding second scale section 221, so that the relative position of the mark pattern 3 corresponding to the second scale section 221 can be determined based on the second scale gradations of the two second measurement sections sm.

In one embodiment of the present invention, the linewidth of each second scale section 221 of the second ruler pattern 22 for inspecting the mark pattern 3 may be adjusted according to the linewidth of the corresponding pattern contour of that layer. This allows each second scale section 221 of the second ruler pattern 22 to potentially have the same or different dimensions. In one embodiment of the present invention, any two adjacent second scale sections 221 of the second ruler pattern 22 maintain a second spacing which is not less than 1 µm.

Accordingly, by utilizing the first ruler pattern 21 and the second ruler pattern 22 of the M^{th} ruler pattern group 2 to inspect whether anomalies occur in different directions between the pattern contour of one layer relative to the pattern contour of another layer, an accuracy of the pattern contours of the plurality layers formed by stacking on the surface of die 1 is ensured more easily.

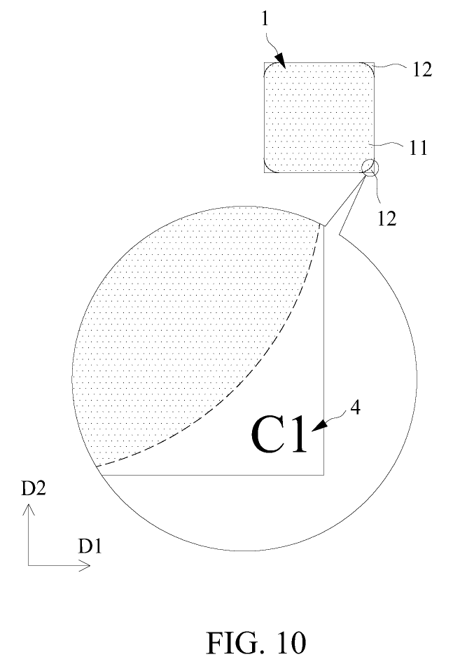

Please refer to FIGS. 1 and 10 together. FIG. 10 is a schematic diagram showing one number pattern 4 of the wafer processing method according to the present invention. For another embodiment of the present invention, in Step S2, the wafer processing method of the present invention further comprises: forming a number pattern on the surface of another one of the plurality of blank areas on each die in the N^{th} photolithography process.

As shown in FIGS. 1 and 10, as performing the photolithography processes N times in the aforementioned Step S2, the present invention may further form one number pattern 4 on the surface of another one of the plural blank areas 12 on each die 1 in the N^{th} photolithography process (i.e., the final photolithography process). That is to say, each set of ruler pattern groups 2 and each mark pattern 3 are formed on the blank area 12 different from that of the number pattern 4. In response to the formation of the number pattern 4, in one embodiment of the present invention, the N^{th} photomask further includes a number pattern area. However, the present invention is not limited thereto.

In one embodiment of the present invention, depending on different designs or requirements, each die 1 on the same wafer 1000 may adopt the same number pattern 4 (e.g., all C1), or one die cluster among the plurality of dies 1 on the same wafer 1000 may adopt consecutive number patterns 4 (e.g., four adjacent dies forming a rectangular block are grouped as one die cluster, with the number patterns 4 of C1, C2, C3 and C4 for the four dies respectively), or those dies 1 on the same wafer 1000 may adopt sequentially different number patterns 4 (e.g., C1, C2, C3, C4, …etc.). Accordingly, when an anomaly is detected in the pattern contour of any layer through the ruler pattern group and the mark pattern formed by the wafer processing method of the present invention, problematic dies 1 within the same cluster or the same batch can be instantly identified based on the corresponding number patterns 4 of the dies 1.

In summary, the wafer processing method of the present invention, in the multiple photolithography processes necessarily required, simultaneously forms corresponding sets of the ruler patterns and/or the mark patterns on the blank areas of each surface of each die as forming the pattern contour of each layer. Accordingly, by observing the relative position of each mark pattern corresponding to the set of ruler pattern groups, abnormalities in the pattern contour of each layer can be readily detected, so as to timely identify problematic dies of the same batch. In contrast, conventional techniques necessitate cross-sectional slice analyzing on dies, which significantly increases inspection costs. This further demonstrates that the present invention has advantageous effects.

The above implementations are only auxiliary descriptions, and are not intended to limit the embodiments of the application subject or the applications or uses of the embodiments. In addition, although at least one illustrative example has been presented above, it should be understood that the present invention can still have a large quantity of variations. It should also be understood that the embodiments described herein are not intended to limit the scope, use, or configuration of the requested subject matter in any way. On the contrary, the foregoing embodiments will provide a convenient guide for those skilled in the art to implement one or more embodiments. Furthermore, various changes can be made to the function and arrangement of the components without departing from the scope defined by the patent claims, and the scope of the patent claims includes known equivalents and all foreseeable equivalents at the time that the patent application is filed.

What is claimed is:

1. A wafer processing method, comprising following steps:
providing a wafer, wherein the wafer includes a plurality of dies and a plurality of blank areas defined near edges of each die; and
performing photolithography processes N times to form N-layer pattern contours on a surface of each die, wherein, except the last photolithography process, each of the remaining N photolithography processes forms a ruler pattern group correspondingly on one of the plurality of blank areas, wherein, except the first photolithography process, each of the remaining N photolithography processes forms a mark pattern correspondingly on each ruler pattern group, already formed , and wherein N is an integer not less than 2;
wherein, by inspecting a relative position of any mark pattern on any ruler pattern group, whether the pattern contour of the corresponding layer exhibits abnormalities can be determined.

2. The wafer processing method as claimed in claim 1, wherein, in each photolithography process, a linewidth of the pattern contour of one layer is equal to a linewidth of the mark pattern formed on each ruler pattern group in the same photolithography process.

3. The wafer processing method as claimed in claim 1, wherein a M^{th} photolithography process is correspondingly performed through a M^{th} photomask for each die, wherein M is an integer and M = 1 to (N-1), wherein when M = 1, the M^{th} photomask includes a M^{th} pattern contour area and a M^{th} ruler pattern area, and wherein when M > 1, the M^{th} photomask includes the M^{th} pattern contour area, the M^{th} ruler pattern area, and a (M-1) ^{th} mark pattern area.

4. The wafer processing method as claimed in claim 3, wherein a N^{th} photolithography process is correspondingly performed through a N^{th} photomask for each die, and the N^{th} photomask includes a N^{th} pattern contour area and a (N-1) ^{th} mark pattern area.

5. The wafer processing method as claimed in claim 4, wherein the N^{th} photomask further includes a number pattern area.

6. The wafer processing method as claimed in claim 3, wherein the M^{th} ruler pattern group is formed through performing the M^{th} photolithography process, the M^{th} ruler pattern group includes a first ruler pattern extending along a first direction, and the first ruler pattern has (N-M) first scale sections.

7. The wafer processing method as claimed in claim 6, wherein each first scale section has two first measuring segments, arranged along the first direction on opposite sides of the first scale section respectively, and at least one first scale gradation is provided along the first direction on each first measuring section.

8. The wafer processing method as claimed in claim 6, wherein the M^{th} ruler pattern group further includes a second ruler pattern extending along a second direction, the second ruler pattern has (N-M) second scale sections, and the second direction is perpendicular to the first direction.

9. The wafer processing method as claimed in claim 8, wherein each second scale section has two second measuring segments, arranged along the second direction on opposite sides of the second scale section respectively, and at least one second scale gradation is provided along the second direction on each second measuring section.

10. The wafer processing method as claimed in claim 1, further comprising a following step:
forming a number pattern on the surface of another one of the plurality of blank areas on each die in the N^{th} photolithography process.
